(19) United States
(12) Patent Application Publication
(10) Pub. No.: US 2019/0196263 A1
(43) Pub. Date: Jun. 27, 2019

(54) DISPLAY PANEL AND DISPLAY DEVICE

(71) Applicant: HUIZHOU CHINA STAR OPTOELECTRONICS TECHNOLOGY CO., LTD., Huizhou Guangdong (CN)

(72) Inventor: Chunchi CHEN, Huizhou Guangdong (CN)

(21) Appl. No.: 15/975,448

(22) Filed: May 9, 2018

Related U.S. Application Data
(63) Continuation of application No. PCT/CN2018/073060, filed on Jan. 17, 2018.

(30) Foreign Application Priority Data
Dec. 26, 2017 (CN) 201711435849.1

(51) Int. Cl. G02F 1/1335; G02F 1/1337; H01L 27/12

(52) U.S. Cl. CPC G02F 1/133528; G02F 1/1337; H01L 27/1214; G02F 1/133602; G02F 1/133514

(57) ABSTRACT

The present invention provides a display panel, which includes a first liquid crystal panel and a second liquid crystal panel. The first and second liquid crystal panels both have VA (vertical alignment) display modes, the first and second liquid crystal panels are disposed face to face, and the first liquid crystal panel is disposed on the second liquid crystal panel. The present invention is to use the stacking structure of dual liquid crystal panels so as to significantly improve the contrast of the display panel, and a rate of light leakage of the display panel can also be sharply decreased.

### RELATED APPLICATIONS

This application is a continuation application of PCT Patent Application No. PCT/CN2018/073060, filed Jan. 17, 2018, which claims the priority benefit of Chinese Patent Application No. 201711435849.1, filed Dec. 26, 2017, which is herein incorporated by reference in its entirety.

### FIELD OF THE DISCLOSURE

The disclosure relates to a display technical field, and more particularly to a display panel and a display device.

### BACKGROUND

With the progress of optoelectronic and semiconductor technologies, the development of flat panel displays has also been driven. In many flat panel displays, Liquid Crystal Display (LCD) has advantages of high space utilization efficiency, low power consumption, zero radiation, low electromagnetic interference, and many other superior features, and has become the mainstream of the market.

LCD usually includes a liquid crystal panel and a backlight module. The backlight module provides light to the liquid crystal panel so that the liquid crystal panel displays an image. However, in a conventional liquid crystal display device with a single liquid crystal panel, the display contrast of which is low, and the light leakage is also serious.

### SUMMARY

A technical problem to be solved by the disclosure is to provide a display panel and a display device with significantly improved contrast.

An objective of the present invention is to provide a display panel, which includes a first liquid crystal panel and a second liquid crystal panel. The first and second liquid crystal panels both have VA (vertical alignment) display modes, the first and second liquid crystal panels are disposed face to face, and the first liquid crystal panel is disposed on the second liquid crystal panel.

Further, the first liquid crystal panel includes a first lower polarizer, a first liquid crystal cell and a first upper polarizer. The first lower polarizer is disposed on the second liquid crystal panel, the first liquid crystal cell is disposed on the first lower polarizer, and the first upper polarizer is disposed on the first liquid crystal cell.

Further, the first liquid crystal cell includes a first color filter substrate, a first array substrate, and a first liquid crystal layer. The first color filter substrate is disposed in between the first upper polarizer and the first lower polarizer, the first array substrate is disposed in between the first color filter substrate and the first lower polarizer, the first array substrate and the first color filter substrate are assembled cassette-to-cassette, and the first liquid crystal layer is disposed in between the first array substrate and the first color filter substrate.

Further, the second liquid crystal panel includes a second lower polarizer, a second liquid crystal cell, and a second upper polarizer. The second liquid crystal cell is disposed on the second lower polarizer, the second upper polarizer is disposed on the second liquid crystal cell, and the first lower polarizer is disposed on the second upper polarizer.

Further, the second liquid crystal cell includes a second color filter substrate, a second array substrate, and a second liquid crystal layer. The second color filter substrate is disposed in between the second upper polarizer and the second lower polarizer, the second array substrate is disposed in between the second color filter substrate and the second lower polarizer, the second array substrate and the second color filter substrate are assembled cassette-to-cassette, and the second liquid crystal layer is disposed in between the second array substrate and the second color filter substrate.

Further, the contrast of the display panel is 27000 times to that of the first liquid crystal panel or the second liquid crystal panel.

According to another aspect of the present invention, the disclosure further provides a display device, which comprises the above display panel, and the backlight module is faced to the second lower polarizer.

Further, the backlight module is a direct-type backlight module or an edge-type backlight module,

Beneficial effects of the present invention: the invention is to use the stacking structure of dual liquid crystal panels so as to significantly improve the contrast of the display panel, and a rate of light leakage of the display panel can also be sharply decreased.

### BRIEF DESCRIPTION OF THE DRAWINGS

Accompanying drawings are for providing further understanding of the abovementioned and other objectives, features, and advantages of the embodiments of the present invention. In the figures:

FIG. 1 is a structural schematic view of a display panel according to an embodiment of the disclosure; and

FIG. 2 is a structural schematic view of a liquid crystal display device according to an embodiment of the disclosure.

### DETAILED DESCRIPTION OF PREFERRED EMBODIMENTS

The present invention is described in details below with references to the accompanying drawings and specific embodiments. However, it is embodied in many different forms and embodiments of the present invention, and the present invention should not be construed as limited to the particular embodiments set forth herein. Rather, these embodiments in order to explain the principles of the invention and its practical application to thereby enable others skilled in the art to understand the invention for various embodiments and various modifications as suited to the particular use contemplated.

In the drawings for device clarity, thicknesses of layers and regions are exaggerated to. The same reference numerals throughout the specification and the drawings may be used to denote like or same elements.

It is understood that, although the terms may be used herein “first,” “second,” etc., to describe various elements, these elements should not be limited by these terms. These terms are only used to distinguish one element from another element.

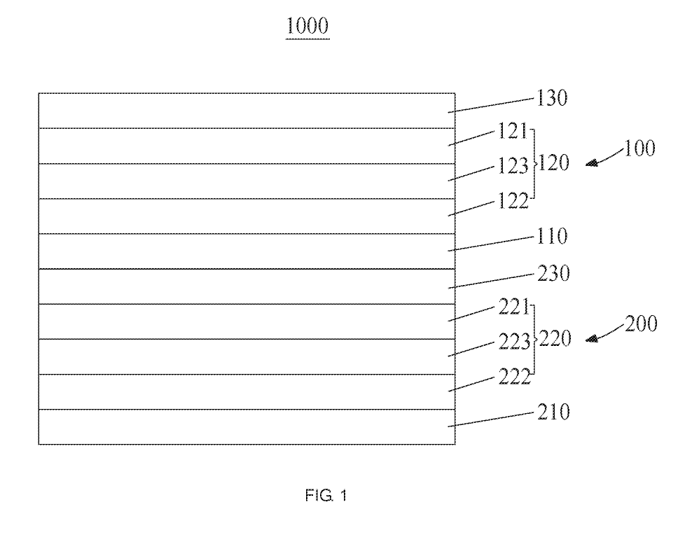

FIG. 1 is a structural schematic view of a display panel according to an embodiment of the disclosure.

As shown in FIG. 1, a display panel 1000 according to an embodiment of the present invention includes a first liquid crystal panel 100 and a second liquid crystal panel 200. The first liquid crystal panel 100 and the second liquid crystal panel 200 both have VA display modes, the first liquid crystal panel 100 and the second liquid crystal panel 200 are disposed face to face, and the first liquid crystal panel 100 is fixed on the second liquid crystal panel 200.

In a preferred embodiment of the present invention, the first liquid crystal panel 100 and the second liquid crystal panel 200 are the same, and each sub-pixel of the first liquid crystal panel 100 is accurately aligned to each sub-pixel of the second liquid crystal panel 200 during the fixation of the first liquid crystal panel 100 and the second liquid crystal panel 200. Thus shadow would not occur when displaying images.

The following Table 1 shows stimulation data of the display panel 1000 and the first liquid crystal panel 100 or the second liquid crystal panel 200.

TABLE 1
Results of Stimulation

| | Brightness of | Brightness of | |
|---|---|---|---|
| Type | White Screen | Black Screen | Contrast |
| First liquid crystal panel | 3782.6 | 0.132223 | 28608 |
| 100 or second liquid crystal | | | |
| panel 200 | | | |
| Display panel 1000 | 3114.7 | 0.000004 | 778675000 |

From the above Table 1, it shows the contrast of the first liquid crystal panel 100 or the second liquid crystal panel 200 is 28608, and the contrast of the display panel 1000 is 27219 times to the contrast of the first liquid crystal panel 100 or the second liquid crystal panel 200. Therefore, the contrast of the display panel 1000 is significantly improved. Moreover, after testing, the light leakage rate of the display panel 1000 is decreased by 3 hundred thousand times than the light leakage rate of the first liquid crystal panel 100 or the second liquid crystal panel 200.

Further, in the embodiment, the first liquid crystal panel 100 includes a first lower polarizer 110, a first liquid crystal cell 120 and a first upper polarizer 130. More specifically, the first lower polarizer 110 is disposed on the second liquid crystal panel 200, the first liquid crystal cell 120 is disposed on the first lower polarizer 110, and the first upper polarizer 130 is disposed on the first liquid crystal cell 120. In the embodiment, relationship between absorptions axes of the first upper polarizer 130 and the first lower polarizer 110 is depending on the normally black mode or normally white mode of the first liquid crystal panel 100, and the invention is not limited herein.

In addition, as an implementation of the present invention, the first liquid crystal cell 120 includes a first color filter substrate 121, a first array substrate 122, and a first liquid crystal layer 123. More specifically, the first color filter substrate 121 is disposed in between the first upper polarizer 130 and the first lower polarizer 110, the first array substrate 122 is disposed in between the first color filter substrate 121 and the first lower polarizer 110, the first array substrate 122 and the first color filter substrate 121 are assembled cassette-to-cassette, and the first liquid crystal layer 123 is disposed in between the first array substrate 122 and the first color filter substrate 121.

Herein, the first color filter substrate 121 can include essential components such as color filter, black matrix, etc. . . . And the first array substrate 122 can include essential components such as thin film transistors, pixel electrodes, etc. . . . The first liquid crystal layer 123 includes a great number of liquid crystal molecules. The liquid crystal molecules are deflected according to the applied voltage to allow light pass through or not. Or as another implementation of the present invention, the color filter is fabricated on the first array substrate 122 to form a COA (color filter on array) substrate.

Furthermore, in the embodiment, the second liquid crystal panel 200 includes a second lower polarizer 210, a second liquid crystal cell 220, and a second upper polarizer 230. More specifically, the second liquid crystal cell 220 is disposed on the second lower polarizer 210, the second upper polarizer 230 is disposed on the second liquid crystal cell 220, and the first lower polarizer 110 is disposed on the second upper polarizer 230. In this embodiment, relationship between absorptions axes of the second upper polarizer 230 and the second lower polarizer 210 is depending on the normally black mode or normally white mode of the second liquid crystal panel 200; however the invention is not limited herein.

In addition, as an implementation of the present invention, the second liquid crystal cell 220 includes a second color filter substrate 221, a second array substrate 222, and a second liquid crystal layer 223. More specifically, the second color filter substrate 221 is disposed in between the second upper polarizer 230 and the second lower polarizer 210, the second array substrate 222 is disposed in between the second color filter substrate 221 and the second lower polarizer 210, the second array substrate 222 and the second color filter substrate 221 are assembled cassette-to-cassette, and the second liquid crystal layer 223 is disposed in between the second array substrate 222 and the second color filter substrate 221.

Herein, the second color filter substrate 221 can include essential components, such as color filter, black matrix, etc. . . . And the second array substrate 222 can include essential components, such as thin film transistors, pixel electrodes, etc. . . . The second liquid crystal layer 223 includes a great number of liquid crystal molecules. The liquid crystal molecules are deflected according to the applied voltage to allow light pass through or not. Or as another implementation of the present invention, the color filter is fabricated on the first array substrate 222 to form a CGA (color filter on array) substrate.

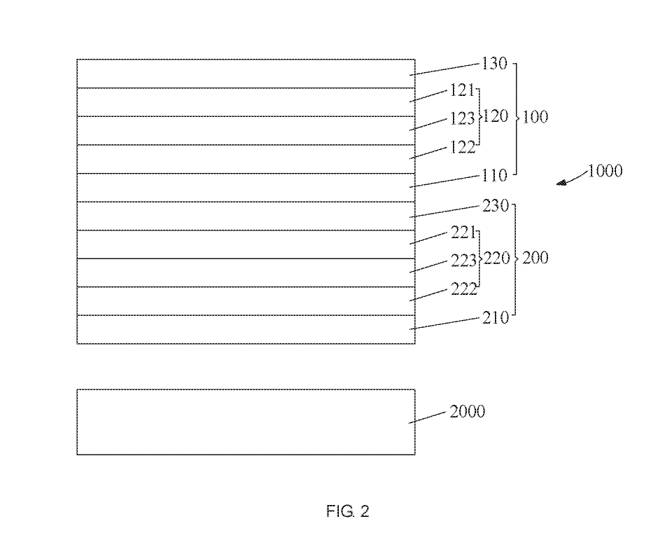

FIG. 2 is a structural schematic view of a display device according to an embodiment of the disclosure.

As shown in FIG. 2, a display device according to an embodiment of the present invention includes the display panel 1000 and a backlight module 2000. The backlight module 2000 and the liquid crystal panel 1000 are disposed opposite to each other, so that the backlight module 2000 can proved light to the liquid crystal panel 1000 to display. Further, the backlight module 2000 is faced to the second lower polarizer 210.

Moreover, in the embodiment, the backlight module 2000 is a direct-type backlight module or an edge-type backlight module, but the present invention is not limited herein.

In conclusion, the invention is to use the stacking structure of dual liquid crystal panels so as to significantly improve the contrast of the display panel, and a rate of light leakage of the display panel can also be sharply decreased.

While shown already with reference to specific embodiments and description in the disclosure, those skilled in the art will appreciate that: without departing from the spirit and scope of the invention being indicated by the claims and their equivalents, various changes in form and detail can be made and should be included in the protection scope of the application.

1. A display panel, comprising:
a first liquid crystal panel; and
a second liquid crystal panel,
wherein the first liquid crystal panel and the second liquid crystal panel both have VA (vertical alignment) display modes, the first liquid crystal panel and the second liquid crystal panels are disposed face to face, and the first liquid crystal panel is disposed on the second liquid crystal panel,
wherein a contrast of the display panel is 27,000 times to a contrast of the first liquid crystal panel or the second liquid crystal panel.

2. The display panel according to claim 1, wherein the first liquid crystal panel comprises:
a first lower polarizer;
a first liquid crystal cell; and
a first upper polarizer,
wherein the first lower polarizer is disposed on the second liquid crystal panel, the first liquid crystal cell is disposed on the first lower polarizer, and the first upper polarizer is disposed on the first liquid crystal cell.

3. The display panel according to claim 2, wherein the first liquid crystal cell comprises:
a first color filter substrate;
a first array substrate; and
a first liquid crystal layer,
wherein the first color filter substrate is disposed in between the first upper polarizer and the first lower polarizer, the first array substrate is disposed in between the first color filter substrate and the first lower polarizer, the first array substrate and the first color filter substrate are assembled cassette-to-cassette, and the first liquid crystal layer is disposed in between the first array substrate and the first color filter substrate.

4. The display panel according to claim 2, wherein the second liquid crystal panel comprises:
a second lower polarizer;
a second liquid crystal cell; and
a second upper polarizer,
wherein the second liquid crystal cell is disposed on the second lower polarizer, the second upper polarizer is disposed on the second liquid crystal cell, and the first lower polarizer is disposed on the second upper polarizer.

5. The display panel according to claim 3, wherein the second liquid crystal panel comprises:
a second lower polarizer;
a second liquid crystal cell; and
a second upper polarizer,
wherein the second liquid crystal cell is disposed on the second lower polarizer, the second upper polarizer is disposed on the second liquid crystal cell, and the first lower polarizer is disposed on the second upper polarizer.

6. The display panel according to claim 4, wherein the second liquid crystal cell comprises:
a second color filter substrate;
a second array substrate; and
a second liquid crystal layer,
wherein the second color filter substrate is disposed in between the second upper polarizer and the second lower polarizer, the second array substrate is disposed in between the second color filter substrate and the second lower polarizer, the second array substrate and the second color filter substrate are assembled cassette-to-cassette, and the second liquid crystal layer is disposed in between the second array substrate and the second color filter substrate.

7. The display panel according to claim 5, wherein the second liquid crystal cell comprises:
a second color filter substrate;
a second array substrate; and
a second liquid crystal layer,
wherein the second color filter substrate is disposed in between the second upper polarizer and the second lower polarizer, the second array substrate is disposed in between the second color filter substrate and the second lower polarizer, the second array substrate and the second color filter substrate are assembled cassette-to-cassette, and the second liquid crystal layer is disposed in between the second array substrate and the second color filter substrate.

8. (canceled)

9. A display device, comprising:
a backlight module; and
the display panel according to claim 1, wherein the backlight module is faced to the second lower polarizer.

10. The display device according to claim 9, wherein the backlight module is a direct-type backlight module or an edge-type backlight module.

11. The display device according to claim 9, wherein the first liquid crystal panel comprises:
a first lower polarizer;
a first liquid crystal cell; and
a first upper polarizer,
wherein the first lower polarizer is disposed on the second liquid crystal panel, the first liquid crystal cell is disposed on the first lower polarizer, and the first upper polarizer is disposed on the first liquid crystal cell.

12. The display device according to claim 11, wherein the first liquid crystal cell comprises:
a first color filter substrate;
a first array substrate; and
a first liquid crystal layer,
wherein the first color filter substrate is disposed in between the first upper polarizer and the first lower polarizer, the first array substrate is disposed in between the first color filter substrate and the first lower polarizer, the first array substrate and the first color filter substrate are assembled cassette-to-cassette, and the first liquid crystal layer is disposed in between the first array substrate and the first color filter substrate.

13. The display device according to claim 11, wherein the second liquid crystal panel comprises:
a second lower polarizer;
a second liquid crystal cell; and
a second upper polarizer,
wherein the second liquid crystal cell is disposed on the second lower polarizer, the second upper polarizer is disposed on the second liquid crystal cell, and the first lower polarizer is disposed on the second upper polarizer.

14. The display device according to claim 12, wherein the second liquid crystal panel comprises:
a second lower polarizer;
a second liquid crystal cell; and
a second upper polarizer,
wherein the second liquid crystal cell is disposed on the second lower polarizer, the second upper polarizer is disposed on the second liquid crystal cell, and the first lower polarizer is disposed on the second upper polarizer.

15. The display device according to claim 13, wherein the second liquid crystal cell comprises:
a second color filter substrate;
a second array substrate; and
a second liquid crystal layer,
wherein the second color filter substrate is disposed in between the second upper polarizer and the second lower polarizer, the second array substrate is disposed in between the second color filter substrate and the second lower polarizer, the second array substrate and the second color filter substrate are assembled cassette-to-cassette, and the second liquid crystal layer is disposed in between the second array substrate and the second color filter substrate.

16. The display device according to claim 14, wherein the second liquid crystal cell comprises:
a second color filter substrate;
a second array substrate; and
a second liquid crystal layer,
wherein the second color filter substrate is disposed in between the second upper polarizer and the second lower polarizer, the second array substrate is disposed in between the second color filter substrate and the second lower polarizer, the second array substrate and the second color filter substrate are assembled cassette-to-cassette, and the second liquid crystal layer is disposed in between the second array substrate and the second color filter substrate.

17. (canceled)
